(19) United States
(12) Patent Application Publication
(10) Pub. No.: US 2013/0175496 A1
(43) Pub. Date: Jul. 11, 2013

(54) SEMICONDUCTOR MEMORY DEVICE, MEMORY CHIP, MEMORY MODULE, MEMORY SYSTEM AND METHOD FOR FABRICATING THE SAME

(71) Applicant: Hye-Jung CHOI, Gyeonggi-do (KR)

(72) Inventor: Hye-Jung CHOI, Gyeonggi-do (KR)

(21) Appl. No.: 13/595,210

(22) Filed: Aug. 27, 2012

(30) Foreign Application Priority Data
Jan. 11, 2012 (KR) 10-2012-0003513

(51) Int. Cl. H01L 27/26; H01L 47/00

(52) U.S. Cl. 257/5; 438/382; 257/E47.005; 257/E27.002

(57) ABSTRACT

A semiconductor memory device and a method for fabricating the same capable of easily controlling a contact area between a conductive line and a memory layer even at the high degree of integration. The semiconductor memory device includes a plurality of first conductive lines, a memory layer contacting with a first sidewall of each of the first conductive lines, and a plurality of second conductive lines crossing the first conductive lines and contacting with the memory layer.

### CROSS-REFERENCE TO RELATED APPLICATIONS

The present application claims priority of Korean Patent Application No. 10-2012-0003513, filed on Jan. 11, 2012, which is incorporated herein by reference in its entirety.

### BACKGROUND

1. Field

Exemplary embodiments of the present invention relate to a technology of fabricating a semiconductor device, and more particularly, to a semiconductor memory device including a memory chip, a memory module, and a memory system and using a change in resistance, such as a resistive random access memory (ReRAM) device, and a method for fabricating a semiconductor memory device.

2. Description of the Related Art

The next generation memory devices capable of replacing a DRAM and a flash memory have been researched. As one of the next generation memory devices, a semiconductor memory device uses variable resistance materials capable of switching between at least two different resistance statuses by sharply changing their own resistance in response to a bias applied thereto.

FIGS. 1A to 1C are diagrams illustrating a conventional semiconductor memory device, wherein FIG. 1A is a plane view, FIG. 1B is a cross-sectional view taken along line I-I′ illustrated in FIG. 1A, and FIG. 1C is a cross-sectional view taken along line II-II′ illustrated in FIG. 1A.

Referring to FIGS. 1A to 1C, the conventional semiconductor memory device using the change in resistance has a structure in which a memory layer 13 made of variable resistance materials is formed at a cross point of a first conductive line 12 and a second conductive line 15 crossing each other.

The semiconductor memory device having the above-mentioned structure is formed by a series of processes including: depositing and etching a conductive layer on a substrate 11 having certain structures to form the first conductive line 12; depositing and etching a variable resistive layer to form the memory layer 13 on the first conductive line 12; forming an insulating layer 14 embedded between the first conductive line 12 and the memory layer 13 on the substrate 11; and forming the second conductive line 15 contacting with the memory layer 13 by depositing and etching a conductive layer on the insulating layer 14.

The conventional semiconductor memory device has a reduced line width of the first and second conductive lines 12 and 15 and the memory layer 13 as the degree of integration thereof is increased, and thus it may be difficult to control a contact area between the first and second conductive lines 12 and 15 and the memory layer 13.

Further, the first and second conductive lines 12 and 15 have a flat panel shape and therefore, as a line width of the first and second conductive lines 12 and 15 is reduced, a volume thereof is reduced correspondingly. As a result, their signal transfer characteristics may be deteriorated.

Further, since the memory layer 13 is formed by the depositing and etching processes, the memory layer 13 may be damaged at the time of the etching process or by-products generated at the time of the etching process may be re-deposited on a sidewall of the memory layer 13, thereby deteriorating characteristics of the memory device.

### SUMMARY

An embodiment of the present invention is directed to a method for easily controlling a contact area between a conductive line and a memory layer even at a high degree of integration.

In addition, an embodiment of the present invention is directed to a method for improving signal transfer characteristics of a conductive line even at a high degree of integration.

Further, an embodiment of the present invention is directed to a method for preventing characteristics from be deteriorated due to a damage of a memory layer and etch by-products.

In accordance with an embodiment of the present invention, a semiconductor memory device includes: a plurality of first conductive lines; a memory layer contacting with a first sidewall of each of the first conductive lines; and a plurality of second conductive lines crossing the first conductive lines and contacting with the memory layer.

In accordance with another embodiment of the present invention, a semiconductor memory device includes: a plurality of first conductive lines formed on a substrate; an insulating layer formed on the first conductive lines; trenches exposing a first sidewall of each of the first conductive lines, a memory layer formed on the exposed sidewall of each of the first conductive lines; and a plurality of second conductive lines crossing the first conductive lines and filling the trenches.

In accordance with another embodiment of the present invention, a method for fabricating a semiconductor memory device includes: forming a plurality of first conductive lines over a substrate; forming an insulating layer over the substrate including the first conductive lines; forming trenches exposing sidewalls of the first conductive lines by selectively etching the insulating layer; forming a memory layer over the exposed sidewalls of the first conductive lines; and forming a plurality of second conductive lines crossing the first conductive lines and filling the trenches.

### BRIEF DESCRIPTION OF THE DRAWINGS

FIGS. 1A to 1C are plan views illustrating a conventional semiconductor memory device.

FIG. 2 is a plan view illustrating a semiconductor memory device in accordance with embodiments of the present invention.

FIGS. 3A and 3B are cross-sectional views illustrating a semiconductor memory device in accordance with a first embodiment of the present invention taken along line I-I′ and line II-II′ illustrated in FIG. 2.

FIGS. 4A and 4B are cross-sectional views illustrating a semiconductor memory device in accordance with a second embodiment of the present invention taken along line I-I′ and line II-II′ illustrated in FIG. 2.

FIGS. 5A to 5E are process cross-sectional views illustrating a method for fabricating the semiconductor memory device in accordance with the second embodiment of the present invention.

FIGS. 6A and 6B are cross-sectional views illustrating a semiconductor memory device in accordance with a third embodiment of the present invention taken along line I-I′ and line II-II′ illustrated in FIG. 2.

FIGS. 7A to 7E are process cross-sectional views illustrating a method for fabricating the semiconductor memory device in accordance with the third embodiment of the present invention.

FIGS. 8A and 8B are process cross-sectional views illustrating another method for fabricating the semiconductor memory device in accordance with the third embodiment of the present invention.

FIG. 9 is a block diagram of a memory chip in accordance with an embodiment of the present invention.

FIG. 10 is a block diagram illustrating a memory module in accordance with an embodiment of the present invention.

FIG. 11 is a block diagram illustrating a memory system in accordance with an embodiment of the present invention.

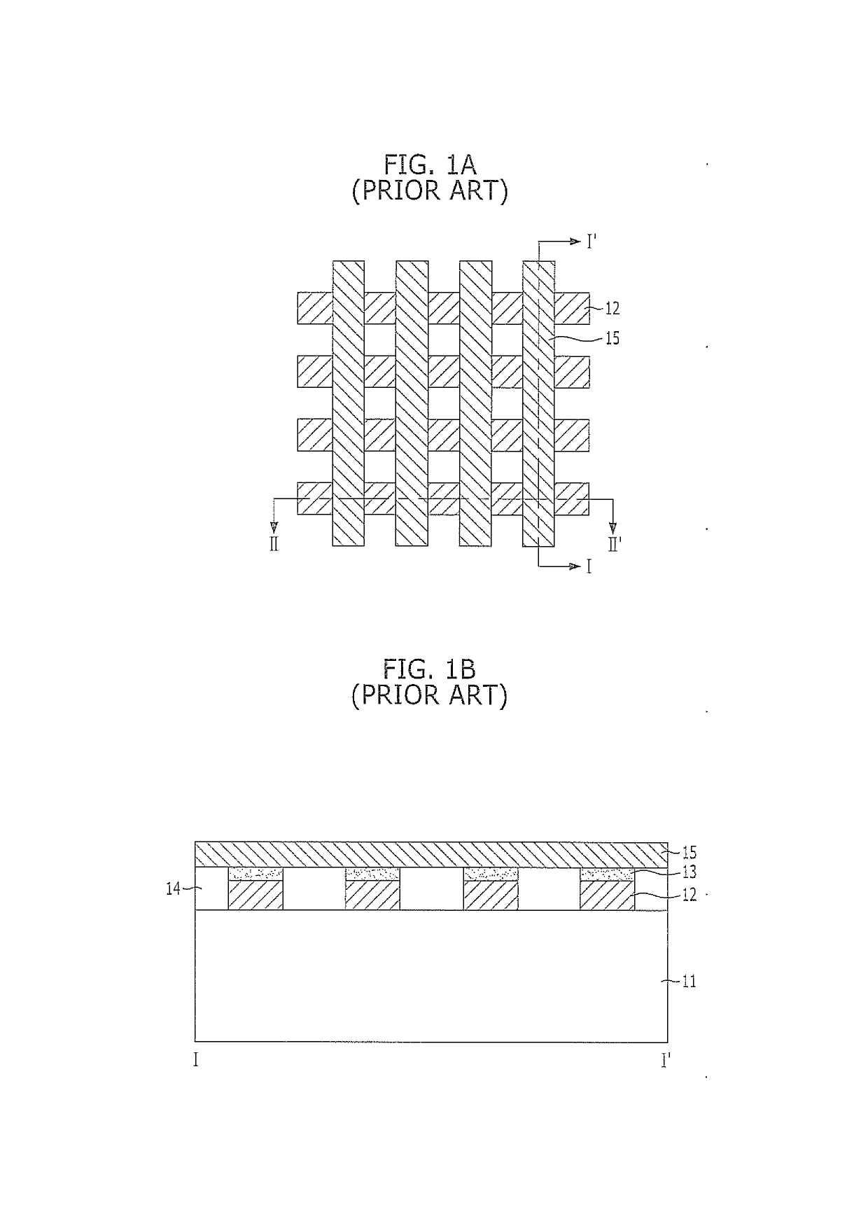

### DETAILED DESCRIPTION

Hereinafter, exemplary embodiments of the present invention will be described with reference to the accompanying drawings so that those of an ordinary skill in the art to which the present invention pertains can easily make and use the embodiments of the present invention. Hereinafter, an embodiment of the present invention provides a semiconductor memory device capable of easily controlling a contact area between a conductive line and a memory layer even at a high degree of integration, improving signal transfer characteristics of the conductive line, and preventing characteristics from being deteriorated due to a damage of the memory layer or etch by-products. To this end, the embodiment of the present invention provides the semiconductor memory device having a structure in which a first conductive line, a memory layer, and a second conductive line are stacked in a horizontal direction, that is, along a surface of a substrate.

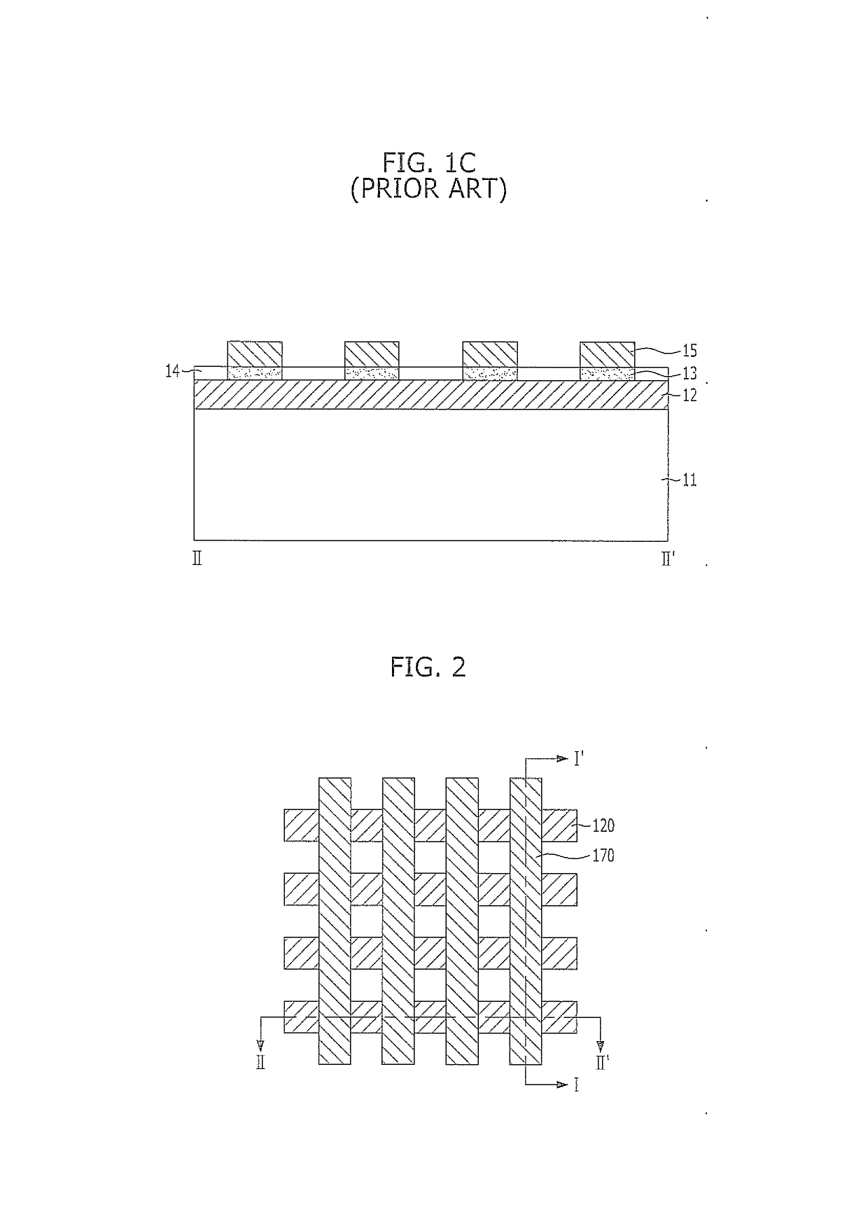

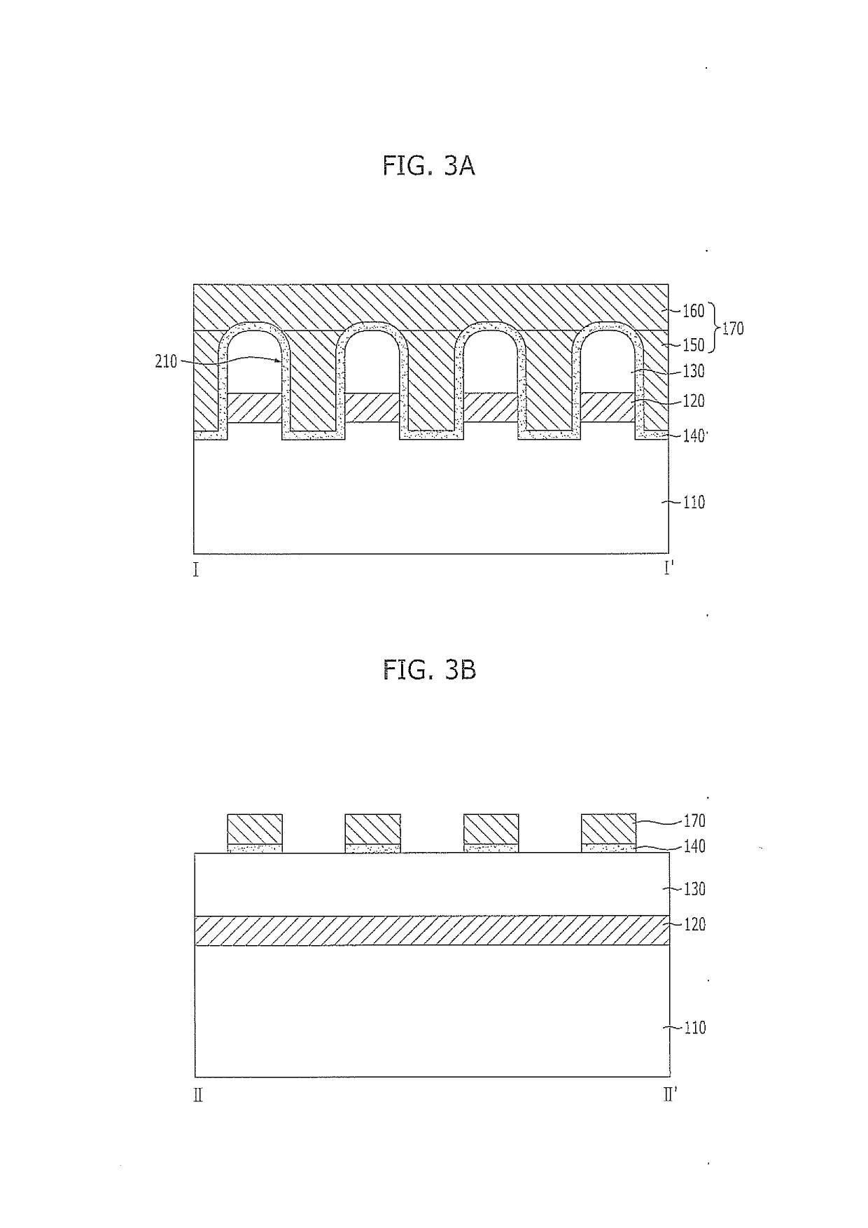

FIG. 2 is a plan view illustrating a semiconductor memory device in accordance with embodiments of the present invention and FIGS. 3A and 3B are cross-sectional views illustrating a semiconductor memory device in accordance with a first embodiment of the present invention taken along line I-I′ and line II-II′ illustrated in FIG. 2.

As illustrated in FIGS. 2, 3A, and 3B, a semiconductor memory device in accordance with a first embodiment of the present invention includes a plurality of first conductive lines 120, a memory layer 140 contacting with both sidewalls of the first conductive lines 120, and a plurality of second conductive lines 170 contacting with the memory layer 140 by extending in a direction crossing with the first conductive lines 120. That is, the semiconductor memory device has a structure in which the first conductive line 120, the memory layer 140, and the second conductive line 170 are stacked in a horizontal direction, that is, along a surface of a substrate 110.

More specifically, the semiconductor memory device includes the plurality of first conductive lines 120 formed on the substrate 110 having certain structures (for example, switching device) formed therein, an insulating layer 130 formed on the substrate 110 including the first conductive lines 120, a trench 210 formed between the insulating layer 130 and exposing both sidewalls of the first conductive line 120, the memory layer 140 formed on the exposed sidewalls of the first conductive line 120, and the plurality of second conductive lines 170 formed on the memory layer 140 to cross the first conductive lines 120 and partially embedded in the trench 210 (i.e., filling the trench 210).

The trench 210 exposing both sidewalls of the first conductive line 120 is to provide a space in which the memory layer 140 is formed while separating the adjacent first conductive lines 120 from each other and may be a line pattern extending in a direction in which the first conductive line 120 extends. In this case, in order to more effectively separate the adjacent first conductive lines 120, the trench 210 may have its bottom surface below the top surface of the substrate 110, that is, the trench 210 may be dug in the substrate 110.

Further, the trench 210 curves at its top side, such that the top side of the trench 210 may have a round shape. This is to increase an inner volume of the trench 210 while reducing process difficulty at the time of a process of forming the memory layer 140 and a process of forming the second conductive line 170. For reference, the trench 210 having the curved top side may improve deposition characteristics at the inlet edge of the trench 210, as compared with the trench 210 having the top side angular with the inlet surface thereof. In addition, the signal transfer characteristics may be improved by increasing the inner volume of the trench 210 and increasing the volume of the second conductive line 170 partially embedded in the trench 210.

The insulating layer 130 may be a single layer of any one selected from a group consisting of an oxide layer, a nitride layer, and an oxynitride layer or a laminate layer in which they are stacked.

The first and second conductive lines 120 and 170 may include a metal layer of any one selected from a group consisting of aluminum (Al), platinum (Pt), ruthenium (Ru), iridium (Ir), nickel (Ni), titanium (Ti), tantalum (Ta), cobalt (Co), chromium (Cr), tungsten (W), copper (Cu), zirconium (Zr), and hafnium (Hf), an alloy layer thereof, or a nitride layer thereof (metal nitride layer).

The second conductive line 170 crossing the first conductive line 120 may include a first conductive layer 150 embedded in the trench 210 and a second conductive layer 160 on the first conductive layer 150. In this case, the first and second conductive layers 150 and 160 may be made of the same materials, or the first conductive layer 150 may be made of materials having more excellent step coverage than that of the second conductive layer 160. The reason why the first conductive layer 150 embedded in the trench 210 is made of materials having more excellent step coverage than that of the second conductive layer 160 is to improve the embedding characteristics of the trench 210.

The memory layer 140 may be formed along the entire surface of the structure including the trench 210 or may remain only in the trench 210. Further, the memory layer 140 may include the variable resistive material. For example, the memory layer 140 may include perovskite-based materials, chalcogenide-based materials, transition metal oxide in the depletion of oxygen, or metal sulfide. An example of perovskite-based materials may include STO (SrTiO) or PCMO (PrCaMnO), an example of chalcogenide-based materials may include GST (GeSbTe), GeSe, CuS, or AgGe, and an example of transition metal oxide may include NiO, TiO₂, HfO, Nb₂O₅, ZnO, ZrO₂, WO₃, CoO, or MnO₂. Further, an example of the metal sulfide may include Cu2S, CdS, or ZnS.

The semiconductor memory device in accordance with the first embodiment of the present invention having the above-mentioned structure has the memory layer 140 contacting with both sidewalls of the first conductive line 120 and the second conductive line 170 partially embedded between the first conductive lines 120, thereby easily controlling the contact area between the first and second conductive lines 120 and 170 and the memory layer 140 by the method of controlling the height of the first conductive line 120 even at the high degree of the integration.

In addition, the second conductive line 170 has a shape in which a portion thereof is embedded in the trench 210 to easily increase the volume of the second conductive line 170, thereby improve the signal transfer characteristics. In addition, as the top side of the trench 210 curves, the signal transfer characteristics of the second conductive line 170 may be further improved.

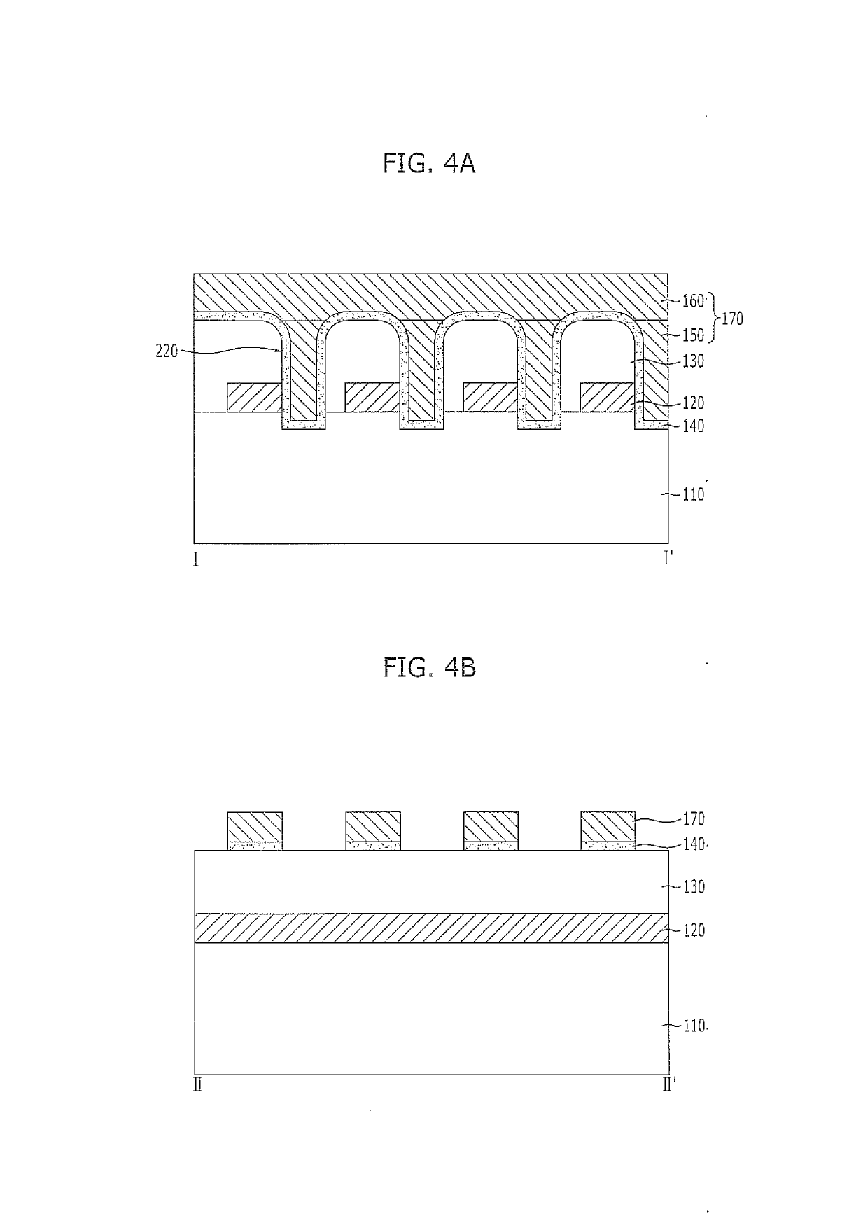

FIG. 2 is a plan view illustrating a semiconductor memory device in accordance with embodiments of the present invention and FIGS. 4A and 4B are cross-sectional views illustrating a semiconductor memory device in accordance with a second embodiment of the present invention taken along line I-I′ and line II-II′ illustrated in FIG. 2. Hereinafter, for the description purposes, the components of the second embodiment of the present invention are denoted by the same reference numerals as the corresponding components of the first embodiment.

As illustrated in FIGS. 2, 4A, and 4B, a semiconductor memory device in accordance with a second embodiment of the present invention includes the plurality of first conductive lines 120, the memory layer 140 contacting with one sidewall of the first conductive lines 120, and the plurality of second conductive lines 170 contacting with the memory layer 140 by extending in a direction crossing with the first conductive lines 120. That is, the semiconductor memory device has a structure in which the first conductive line 120, the memory layer 140, and the second conductive line 170 are stacked in a horizontal direction, that is, along the surface of the substrate 110.

More specifically, the semiconductor memory device includes the plurality of first conductive lines 120 formed on the substrate 110 having certain structures (for example, switching device) formed therein, an insulating layer 130 formed on the substrate 110 including the first conductive lines 120, a trench 220 formed between the insulating layer 130 and exposing one sidewall of the first conductive line 120, the memory layer 140 formed on the exposed sidewall of the first conductive line 120, and the plurality of second conductive lines 170 formed on the memory layer 140 to cross the first conductive lines 120 and partially embedded in the trench 220.

The trench 220 exposing one sidewall of the first conductive line 120 is to provide a space in which the memory layer 140 is formed and may be the line pattern extending in a direction in which the first conductive line 120 extends. In this case, in order to more effectively separate the adjacent first conductive lines 120, the trench 220 may have its bottom surface below the top surface of the substrate 110, that is, the trench 220 may be dug in the substrate 110.

Further, trench 220 curves at its top side, such that the top side of the trench 210 may have a round shape. This is to increase an inner volume of the trench 220 while reducing process difficulty at the time of a process of forming the memory layer 140 and a process of forming the second conductive line 170. For reference, the trench 220 having the curved top side may improve deposition characteristics at the inlet edge of the trench 220, as compared with the trench having the top side angular with the inlet surface thereof. In addition, the signal transfer characteristics may be improved by increasing the inner volume of the trench 220 and increasing the volume of the second conductive line 170 partially embedded in the trench 220.

The insulating layer 130 may be a single layer of any one selected from a group consisting of an oxide layer, a nitride layer, and an oxide nitride layer or a laminate layer in which they are stacked.

The first and second conductive lines 120 and 170 may include a metal layer of any one selected from a group consisting of aluminum (Al), platinum (Pt), ruthenium (Ru), iridium (Ir), nickel (Ni), titanium (Ti), tantalum (Ta), cobalt (Co), chromium (Cr), tungsten (W), copper (Cu), zirconium (Zr), and hafnium (Hf), an alloy layer thereof, or a nitride layer thereof (metal nitride layer).

The second conductive line 170 crossing the first conductive line 120 may include a first conductive layer 150 embedded in the trench 220 and a second conductive layer 160 on the first conductive layer 150. In this case, the first and second conductive layers 150 and 160 may be made of the same materials, or the first conductive layer 150 embedded in the trench 220 may be made of materials having more excellent step coverage than that of the second conductive layer 160. The reason why the first conductive layer 150 embedded in the trench 220 is made of materials having more excellent step coverage than that of the second conductive layer 160 is to improve the embedding characteristics of the trench 220.

The memory layer 140 may be formed along the entire surface of the structure including the trench 220 or may remain only in the trench 220. Further, the memory layer 140 may include the variable resistive material. For example, the memory layer 140 may include perovskite-based materials, chalcogenide-based materials, transition metal oxide in the depletion of oxygen, or metal sulfide. An example of perovskite-based materials may include STO (SrTiO) or PCMO (PrCaMnO), an example of chalcogenide-based materials may include GST (GeSbTe), GeSe, CuS, or AgGe, and an example of transition metal oxide may include NiO, TiO₂, HfO, Nb₂O₅, ZnO, ZrO₂, WO₃, CoO, or MnO₂. Further, an example of the metal sulfide may include Cu2S, CdS, or ZnS.

The semiconductor memory device in accordance with the second embodiment of the present invention having the above-mentioned structure has the memory layer 140 contacting with one sidewall of the first conductive line 120 and the second conductive line 170 partially embedded between the first conductive lines 120, thereby easily controlling the contact area between the first and second conductive lines 120 and 170 and the memory layer 140 by the method of controlling the height of the first conductive line 120 even at the high degree of the integration.

In addition, the second conductive line 170 has a shape in which a portion thereof is embedded in the trench 220 to easily increase the volume of the second conductive line 170, thereby improving the signal transfer characteristics. In addition, as the top side of the trench 220 curves, the signal transfer characteristics of the second conductive line 170 may be further improved.

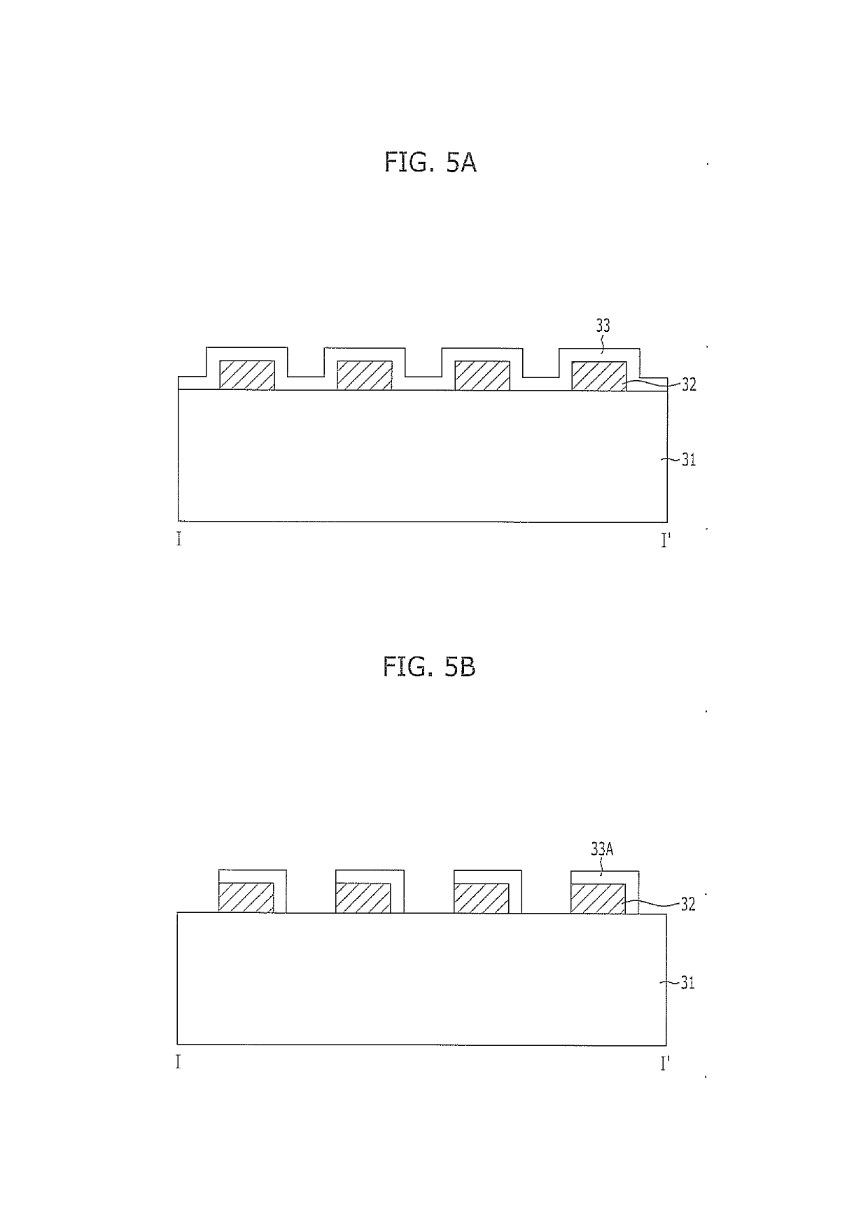

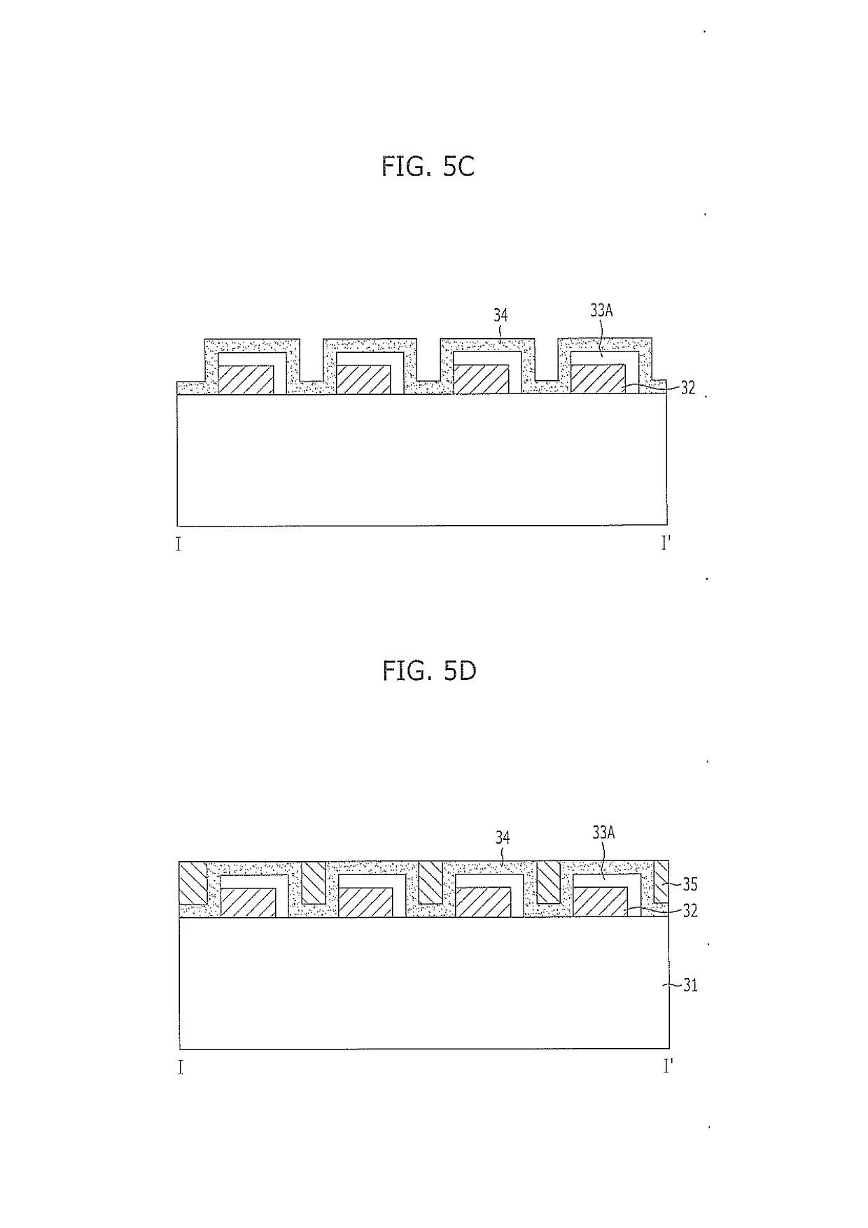

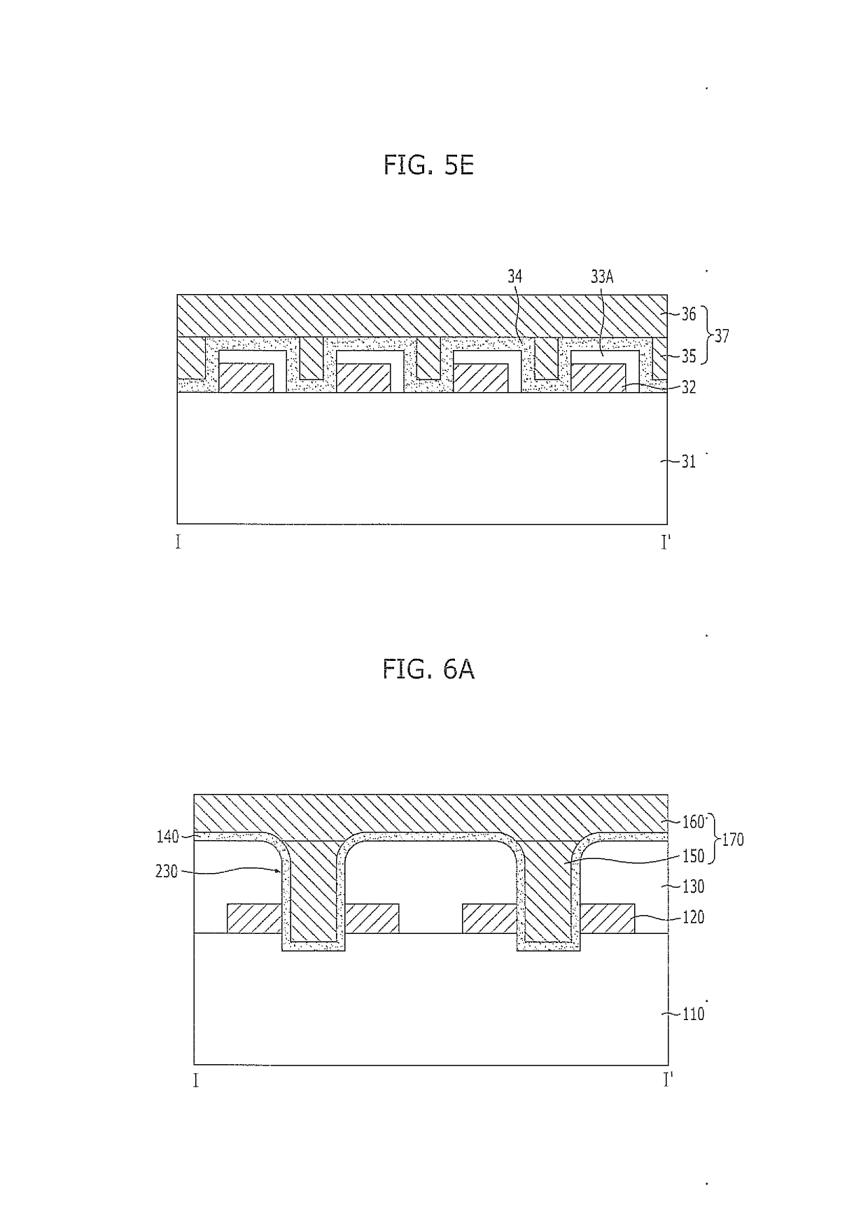

Hereinafter, a method for fabricating a semiconductor memory device in accordance with the second embodiment of the present invention will be described with FIGS. 5A to 5E.

FIGS. 5A to 5E are process cross-sectional views of a method for fabricating the semiconductor memory device in accordance with the second embodiment of the present invention taken along line I-I′ illustrated in FIG. 2.

As illustrated in FIG. 5A, a plurality of first conductive lines 32 (corresponding to the plurality of first conductive lines 120 shown in FIGS. 4A and 4B) are formed on a substrate 31 (corresponding to the substrate 110 shown in FIGS. 4A and 4B) having certain structures formed therein. In this case, the height of the first conductive line 32 may be controlled in consideration of the contact area with the memory layer to be formed through the subsequent process.

The first conductive line 32 may include a metal layer of any one selected from a group consisting of aluminum (Al), platinum (Pt), ruthenium (Ru), iridium (Ir), nickel (Ni), titanium (Ti), tantalum (Ta), cobalt (Co), chromium (Cr), tungsten (W), copper (Cu), zirconium (Zr), and hafnium (Hf), an alloy layer thereof, or a nitride layer thereof (metal nitride layer).

Next, an insulating layer 33 is formed along the surface of the structure including the first conductive line 32. The insulating layer 33 may be formed of a single layer of any one selected from a group consisting of an oxide layer, a nitride layer, and an oxynitride layer or a laminate layer in which they are stacked. For example, the insulating layer 33 may be formed of a nitride layer.

As illustrated in FIG. 5B, an insulating pattern 33A (corresponding to the insulation layer 130 shown in FIGS. 4A and 4B) exposing one sidewall of the first conductive line 32 is formed by selectively etching the insulating layer 33. The insulating pattern 33A may be formed by a series of processes of forming a mask pattern (not illustrated) having an opening part to expose one sidewall of the first conductive line 32 on the insulating layer 33 and then, etching the insulating layer 33 using the mask pattern as the etch barrier.

As illustrated in FIG. 5C, a memory layer 34 (corresponding to the insulation layer 140 shown in FIGS. 4A and 4B) is formed along the surface of the structure including the insulating pattern 33A. Since the memory layer 34 is formed in the state that one sidewall of the first conductive line 32 is exposed by the insulating pattern 33A, the memory layer 34 contacts with one sidewall of the first conductive line 32.

The memory layer 34 may be formed of a material layer having the variable resistance characteristics. For example, the memory layer 34 may include perovskite-based materials, chalcogenide-based materials, transition metal oxide in the depletion of oxygen, or metal sulfide. An example of perovskite-based materials may include STO (SrTiO) or PCMO (PrCaMnO), an example of chalcogenide-based materials may include GST (GeSbTe), GeSe, CuS, or AgGe, and an example of transition metal oxide may include NiO, TiO₂, HfO, Nb₂O₅, ZnO, ZrO₂, WO₃, CoO, or MnO₂. Further, an example of the metal sulfide may include Cu2S, CdS, or ZnS.

Here, since the memory layer 34 contacts with the sidewall of the first conductive line 32 by the insulating pattern 33A, it may be formed without a further etching process. Therefore, the process of manufacturing a semiconductor memory device may be simplified and the deterioration in characteristics due to the damage by the etching of the memory layer 34 and the deterioration in characteristics due to by-products occurring at the time of the etching process may be prevented.

As illustrated in FIG. 5D, after the first conductive layer 35 (corresponding to the first conductive layer 150 shown in FIG. 4A) embedded in a trench between the first conductive lines 32 is formed on the memory layer 34, a planarization process is performed until the memory layer 34 is exposed. The planarization process may be performed using a chemical mechanical polishing method (CMP). Meanwhile, the planarization process may be performed until the insulating pattern 33A is exposed, and the memory layer 34 remains at both sidewalls of the first conductive line 32 by the planarization process.

The first conductive line 35 may include a metal layer of any one selected from a group consisting of aluminum (Al), platinum (Pt), ruthenium (Ru), iridium (Ir), nickel (Ni), titanium (Ti), tantalum (Ta), cobalt (Co), chromium (Cr), tungsten (W), copper (Cu), zirconium (Zr), and hafnium (Hf), an alloy layer thereof, or a nitride layer thereof. In this case, since the first conductive layer 35 is embedded in a trench between the first conductive lines 32, the first conductive layer 35 may be made of materials having excellent step coverage so as to improve the embedding characteristics.

As illustrated in FIG. 5E, the second conductive layer 36 is formed on the top surface of the structure including the first conductive layer 35. The second conductive layer 36 may be made of the same material as the first conductive layer 35.

Next, after the mask pattern (not illustrated) is formed on the second conductive layer 36, the second conductive layer 36, the first conductive layer 35, and the memory layer 34 are sequentially etched using the mask pattern as the etch barrier until the substrate 31 is exposed. A plurality of second conductive lines 37 (corresponding to the plurality of second conductive lines 170 shown in FIGS. 4A and 4B) formed of the first and second conductive layers 35 and 36 and crossing the first conductive line 32 are formed by the above-mentioned etching process.

Next, although not illustrated in the drawings, the insulating layer embedded between the second conductive lines 37 may be formed. Thereafter, the semiconductor memory device having a multi stack structure may be formed by repeating the above-mentioned processes.

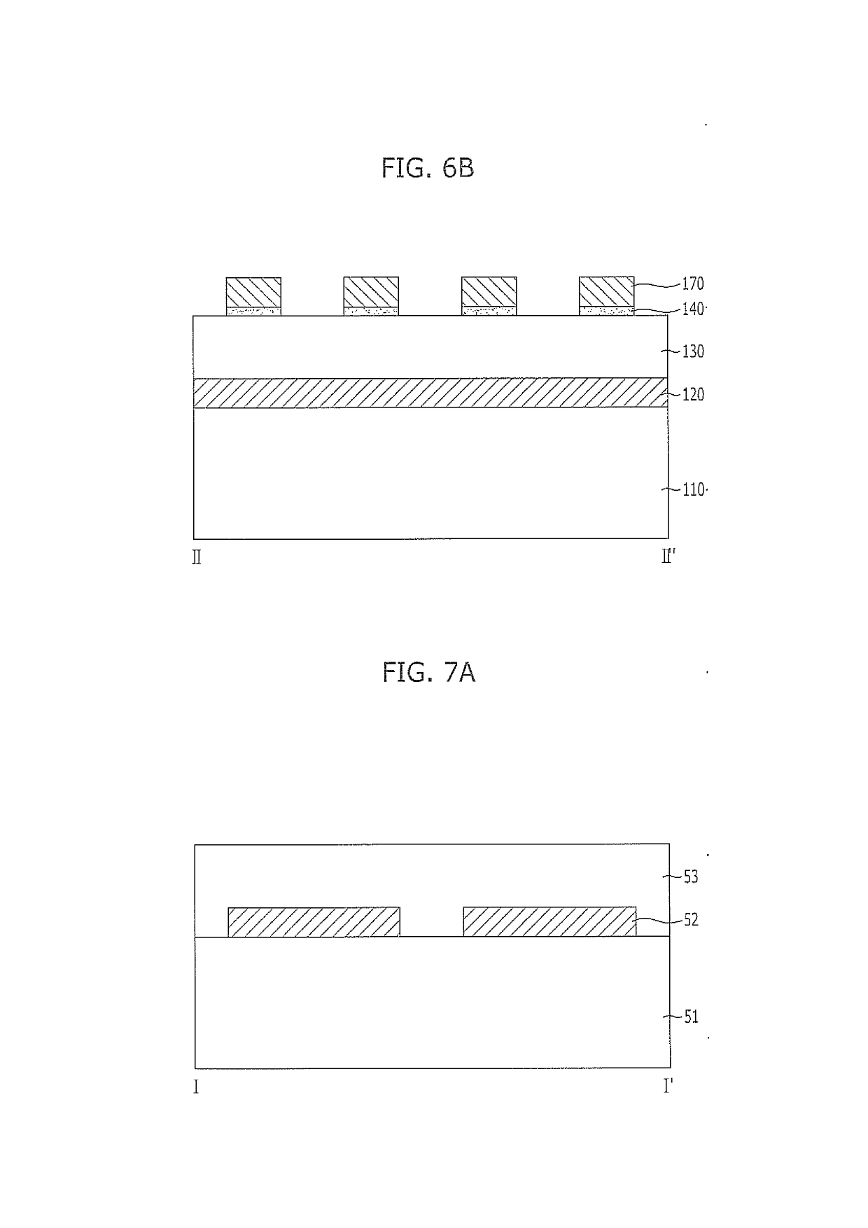

FIG. 2 is a plan view illustrating a semiconductor memory device in accordance with embodiments of the present invention and FIGS. 6A and 6B are cross-sectional views illustrating a semiconductor memory device in accordance with a third embodiment of the present invention taken along line I-I′ and line II-II′ illustrated in FIG. 2. Hereinafter, for the description purposes, the components of the third embodiment of the present invention are denoted by the same reference numerals as the corresponding components of the first embodiment.

As illustrated in FIGS. 2, 6A, and 6B, a semiconductor memory device in accordance with a third embodiment of the present invention includes the plurality of first conductive lines 120, the memory layer 140 contacting with one sidewall or the other sidewall of the first conductive lines 120, and the plurality of second conductive lines 170 contacting with the memory layer 140 by extending in a direction crossing with the first conductive lines 120. That is, the semiconductor memory device has a structure in which the first conductive line 120, the memory layer 140, and the second conductive line 170 are stacked in a horizontal direction, that is, along the surface of the substrate 110. The memory layer 140 contacting with face-to-face sidewalls of each pair of the first conductive lines 120.

More specifically, the semiconductor memory device includes the plurality of first conductive lines 120 formed on the substrate 110 having certain structures (for example, switching device) formed therein, an insulating layer 130 formed on the substrate 110 including the first conductive lines 120, a trench 230 formed between the insulating layer 130 and exposing one sidewall or the other sidewall of the first conductive line 120, the memory layer 140 formed on the exposed sidewall of the first conductive line 120, and the plurality of second conductive lines 170 formed on the memory layer 140 to cross the first conductive lines 120 and partially embedded in the trench 230.

The trench 230 exposing the face-to-face sidewalls of each pair of the first conductive lines 120 is to provide a space in which the memory layer 140 is formed while separating the first conductive tines 120 of the each pair from each other and may be a line pattern extending in a direction in which the first conductive line 120 extends. In this case, in order to more effectively separate the adjacent first conductive lines 120, a trench 230 may have it bottom surface below the top surface of the substrate 110, that is, the trench 230 may be dug in the substrate 110.

Further, the trench 230 curves at its top side, such that the top side of the trench 230 may have a round shape. This is to increase an inner volume of the trench 230 while reducing process difficulty at the time of forming the memory layer 140 and the second conductive line 170. For reference, the trench 230 having the curved top side may improve deposition characteristics at the inlet edge of the trench 230, as compared with the trench having the top side angular with the inlet surface thereof. In addition, the signal transfer characteristics may be improved by increasing the inner volume of the trench 230 and increasing the volume of the second conductive line 170 partially embedded in the trench 230.

In addition, the trench 230 may have a shape in which one sidewall of the even-numbered first conductive line 120 is exposed while one sidewall of the odd-numbered first conductive line 120, which faces the one sidewall of the even-numbered first conductive line 120, is exposed. That is, the trench 230 may have a shape in which one sidewall of an n-th first conductive line 120 (n is a natural number other than 0), among the plurality of first conductive lines 120, is exposed while one sidewall of an n+1-th first conductive line 120, which faces the one sidewall of the n-th first conductive line 120, is exposed, and the insulating layer 130 is embedded between the other sidewall of the n-th first conductive line 120 and one sidewall of the n−1-th first conductive line 120, which faces to the other sidewall of the n-th first conductive line 120.

The insulating layer 130 may be a single layer of any one selected from a group consisting of an oxide layer, a nitride layer, and an oxide nitride layer or a laminate layer in which they are stacked.

The first and second conductive lines 120 and 170 may include a metal layer of any one selected from a group consisting of aluminum (Al), platinum (Pt), ruthenium (Ru), iridium (Ir), nickel (Ni), titanium (Ti), tantalum (Ta), cobalt (Co), chromium (Cr), tungsten (W), copper (Cu), zirconium (Zr), and hafnium (Hf), an alloy layer thereof, or a nitride layer thereof (metal nitride layer).

The second conductive line 170 crossing the first conductive line 120 may include a first conductive layer 150 embedded in the trench 230 and a second conductive layer 160 on the first conductive layer 150. In this case, the first and second conductive layers 150 and 160 may be made of the same materials, or the first conductive layer 150 embedded in the trench 230 may be made of materials having more excellent step coverage than that of the second conductive layer 160. The reason why the first conductive layer 150 embedded in the trench 230 is made of materials having more excellent step coverage than that of the second conductive layer 160 is to improve the embedding characteristics of the trench 230.

The memory layer 140 may be formed along the entire surface of the structure including the trench 230 or may remain only in the trench 230. Further, the memory layer 140 may include the variable resistive material. For example, the memory layer 140 may include perovskite-based materials, chalcogenide-based materials, transition metal oxide in the depletion of oxygen, or metal sulfide. An example of perovskite-based materials may include STO (SrTiO) or PCMO (PrCaMnO), an example of chalcogenide-based materials may include GST (GeSbTe), GeSe, CuS, or AgGe, and an example of transition metal oxide may include NiO, TiO₂, HfO, Nb₂O₅, ZnO, ZrO₂, WO₃, CoO, or MnO₂. Further, an example of the metal sulfide may include Cu2S, CdS, or ZnS.

The semiconductor memory device in accordance with the third embodiment of the present invention having the above-mentioned structure has the memory layer 140 contacting with one sidewall of the first conductive line 120 and the second conductive line 170 partially embedded between the first conductive lines 120, thereby easily controlling the contact area between the first and second conductive lines 120 and 170 and the memory layer 140 by the method of controlling the height of the first conductive line 120 even at the high degree of the integration.

In addition, the second conductive line 170 has a shape in which a portion thereof is embedded in the trench 230 to easily increase the volume of the second conductive line 170, thereby improving the signal transfer characteristics. In addition, as the top side of the trench 230 curves, the signal transfer characteristics of the second conductive line 170 may be further improved.

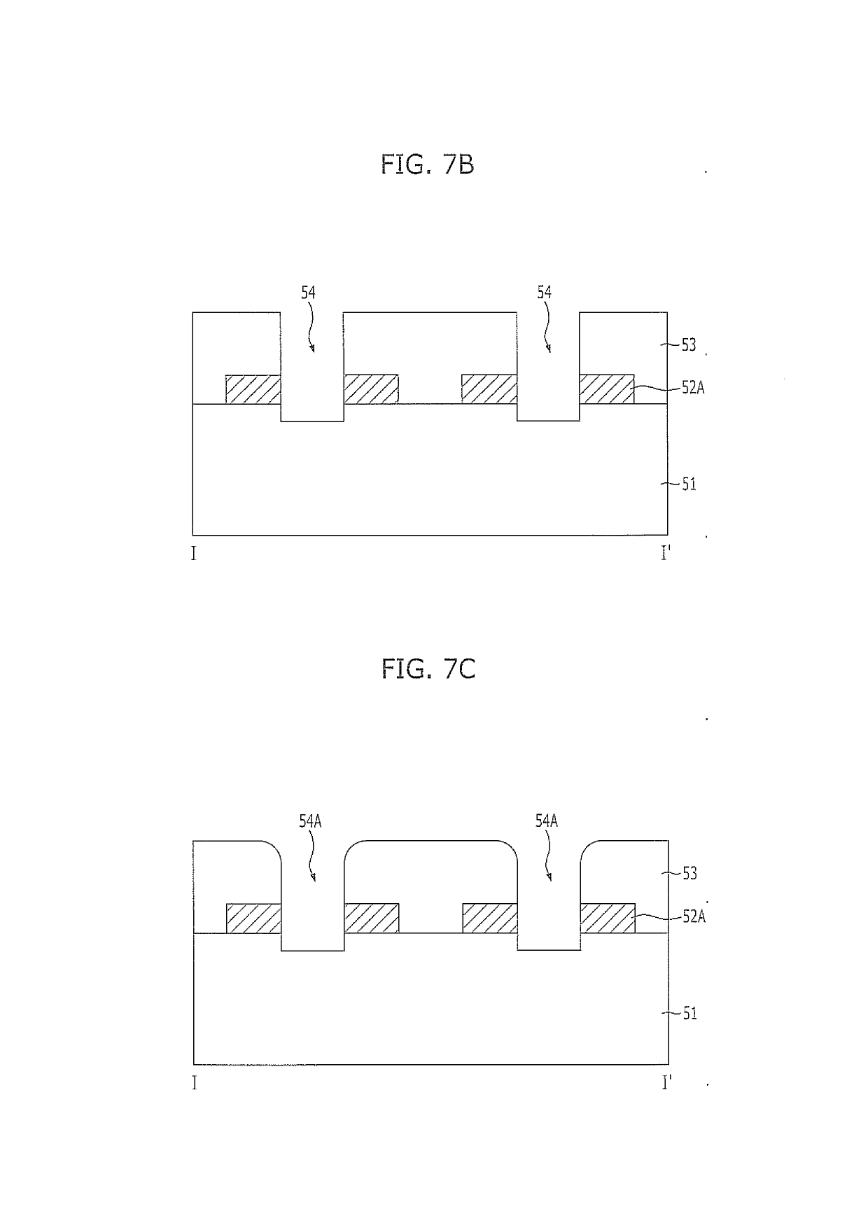

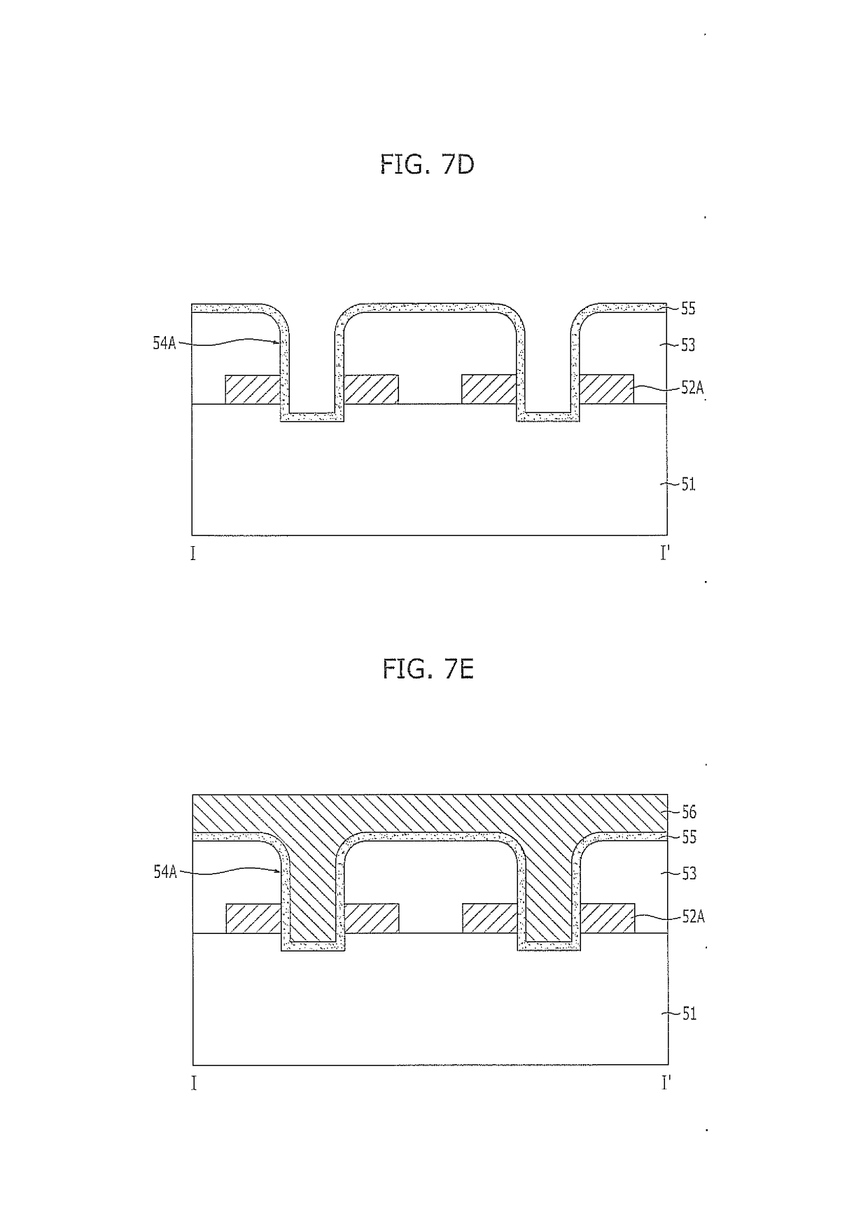

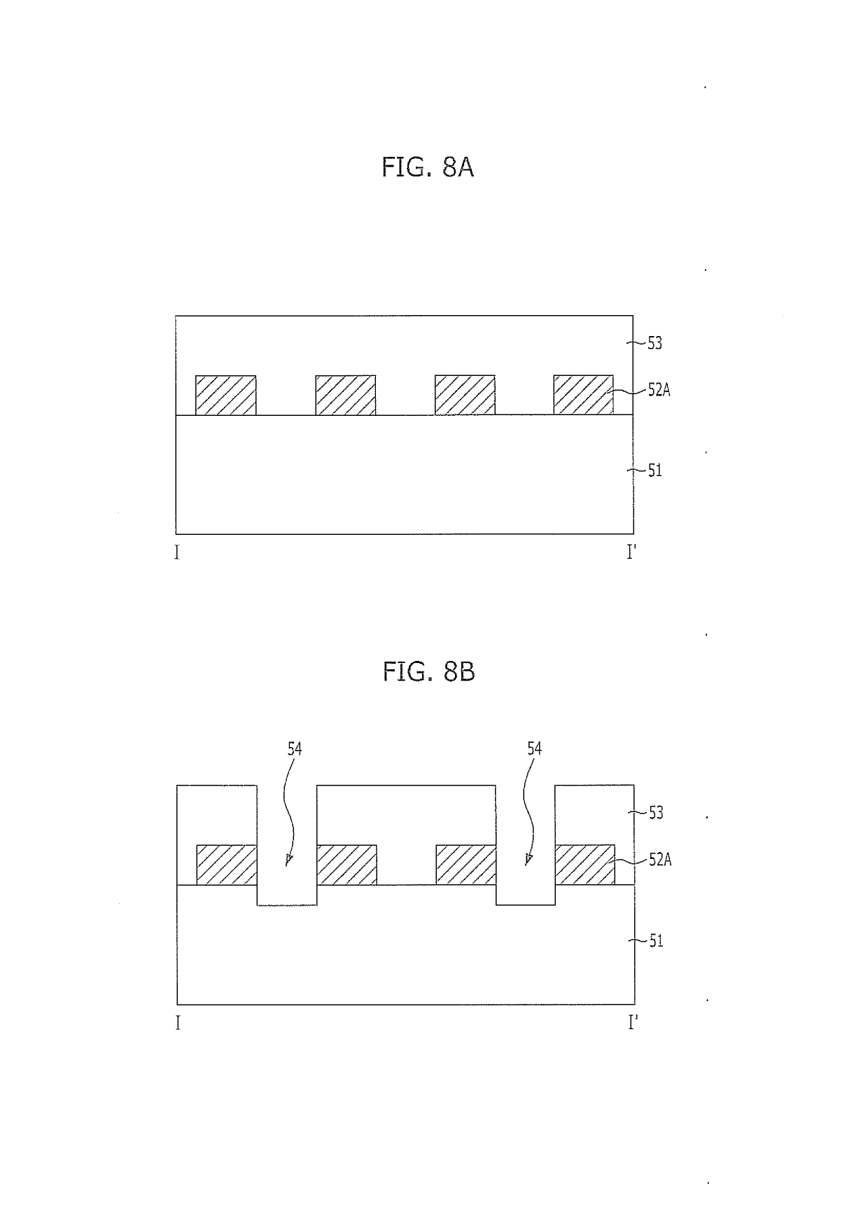

Hereinafter, a method for fabricating a semiconductor memory device in accordance with the third embodiment of the present invention will be described with FIGS. 7A to 7E. A modified example of the method for forming a trench exposing one sidewall or the other sidewall of the first conductive line will be described with reference to FIGS. 8A and 8B.

FIGS. 7A to 7E are process cross-sectional views of a method for fabricating the semiconductor memory device in accordance with an embodiment of the present invention taken along line illustrated in FIG. 2. FIGS. 8A and 8B illustrate another method for fabricating the semiconductor memory device, wherein the corresponding components are denoted by the same reference numerals.

As illustrated in FIG. 7A, a conductive pattern 52 is formed on a substrate 51 having certain structures formed therein. The conductive pattern 52 may form a line pattern extending in one direction and a height of the conductive pattern 52 may be controlled in consideration of the contact area with the memory layer to be formed through the subsequent process.

The conductive line 52 may include a metal layer of any one selected from a group consisting of aluminum (Al), platinum (Pt), ruthenium (Ru), iridium (Ir), nickel (Ni), titanium (Ti), tantalum (Ta), cobalt (Co), chromium (Cr), tungsten (W), copper (Cu), zirconium (Zr), and hafnium (Hf), an alloy layer thereof, or a nitride layer thereof (metal nitride layer).

Next, an insulating layer 53 covering the conductive pattern 52 is formed on the substrate 51. The insulating layer 53 may be formed of a single layer of any one selected from a group consisting of an oxide layer, a nitride layer, and an oxynitride layer or a laminate layer in which they are stacked.

As illustrated in FIG. 7B, after the mask pattern (not illustrated) is formed on the substrate 51, the first conductive line 52A is formed while a trench 54 is formed by etching the insulating layer 53, the conductive pattern 52, and a portion of the substrate 51 using the mask pattern as the etch barrier. In this case, the reason of etching a portion of the substrate 51 is to prevent a short circuit from occurring between the first conducive lines 52A disposed at both sides of the trench 54.

The trench 54 may be formed in a line pattern extending in the same direction as the first conductive line 52A. A line width of the trench 54 may be equal to an interval between the first conductive lines 52A and the first conductive line 52A disposed at both sides of the trench 54 may have the same line width.

While the above embodiment of the present invention forms the trench 54 by etching the conductive pattern 52 and the insulating layer 53, a plurality of first conductive lines 120 and an insulating layer 53 may be formed, and then the trench 54 may be formed by etching the insulating layer 53 so as to relieve the etch burden on the process of forming the trench 54 (see FIGS. 8A and 8B). In this case, since the trench 54 is formed by etching only the insulating layer 53, the process of forming the trench 54 may be more easily performed by relieving the etch burden on the process of forming the trench 54.

As illustrated in FIG. 7C, the top side of the trench 54 is rounded by selectively etching the insulating layer 53. Hereinafter, reference numeral of the trench 54 having the round top side is represented by ‘54A’

The reason of rounding the top side of the trench 54A is to increase the volume of the second conductive lines embedded in the trench 54A through the subsequent process by increasing the inner volume of the trench 54A while more easily performing the deposition of the memory layer to be formed through the subsequent process.

As illustrated in FIG. 7D, a memory layer 55 is formed along the surface of the structure including the trench 54A of which the top side is rounded. In this case, the memory layer 55 is formed to contact with the sidewall of the first conductive line 52A.

The memory layer 55 may be formed of a material layer having the variable resistance characteristics. For example, the memory layer 55 may include perovskite-based materials, chalcogenide-based materials, transition metal oxide in the depletion of oxygen, or metal sulfide. An example of perovskite-based materials may include STO (SrTiO) or PCMO (PrCaMnO), an example of chalcogenide-based materials may include GST (GeSbTe), GeSe, CuS, or AgGe, and an example of transition metal oxide may include NiO, TiO₂, HfO, Nb₂O₅, ZnO, ZrO₂, WO₃, CoO, or MnO₂. Further, an example of the metal sulfide may include Cu2S, CdS, or ZnS.

Here, since the memory layer 55 is formed to contact with the sidewall of the first conductive line 32 by the trench 54A, it may be formed without a further etching process. Therefore, the process of manufacturing a semiconductor memory device may be simplified and the deterioration in characteristics due to the damage by the etching of the memory layer 55 and the deterioration in characteristics due to by-products occurring at the time of the etching process may be prevented.

As illustrated in FIG. 7E, a conductive layer embedded in the trench 54A is formed on the memory layer 55. In this case, the conductive layer may be formed to be partially embedded in the trench 54A and to cover the top of the memory layer 55 and may include a metal layer of any one selected from a group consisting of aluminum (Al), platinum (Pt), ruthenium (Ru), iridium (Ir), nickel (Ni), titanium (Ti), tantalum (Ta), cobalt (Co), chromium (Cr), tungsten (W), copper (Cu), zirconium (Zr), and hafnium (Hf), an alloy layer thereof, or a nitride layer thereof.

Next, the top surface of the conductive layer is planarized by performing the planarization process to form the mask pattern (not illustrated). In this case, the planarization process may be performed using the chemical mechanical polishing (CMP).

Next, a plurality of second conductive lines 56 crossing the first conductive lines 52A and partially embedded in trenches 54A are formed by etching the conductive layer using the mask pattern as the etch barrier. Here, the second conductive lines 56 are formed by etching the conductive layer and the memory layer 55 until the insulating layer 53 and the substrate 51 are exposed. Otherwise, the second conductive lines 56 may be formed by etching the conductive layer until the memory layer 55 is exposed

Next, although not illustrated in the drawings, the insulating layer embedded between the second conductive lines 56 may be formed. Thereafter, the semiconductor memory device having a multi stack structure may be formed by repeating the above-mentioned processes.

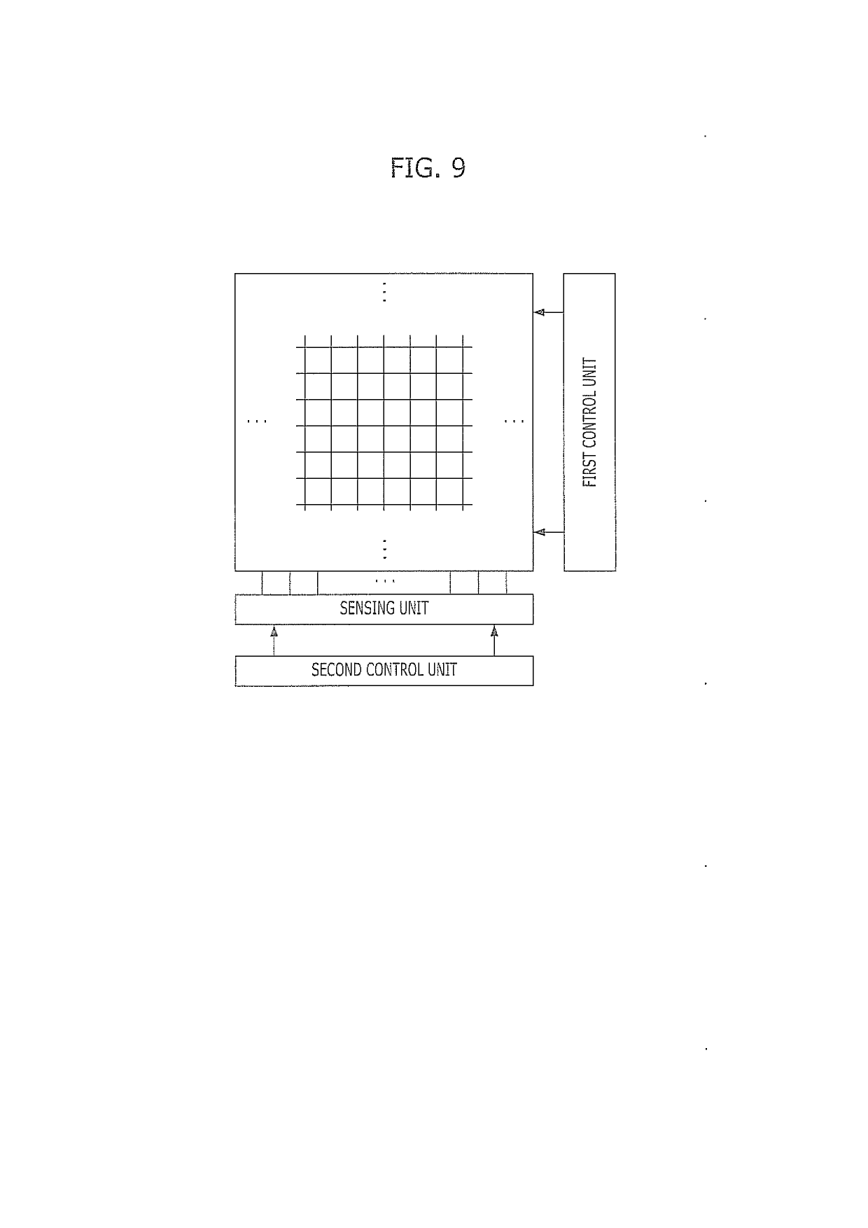

FIG. 9 is a block diagram of a memory chip in accordance with an embodiment of the present invention.

As illustrated in FIG. 9, the memory chip may include the semiconductor memory devices (that is, a plurality of first conductive lines, memory layers contacting with sidewalls of the first conductive lines, and a plurality of second conductive lines crossing the first conductive lines and contacting with the memory layers) in accordance with the embodiments of the present invention, a first control unit, a second control unit, and a sensing unit. The first control unit may be a row decoder, the second control unit may be a column decoder, and the sensing unit may be a sense amplifier.

The first control unit selects the first conductive line corresponding to the memory cell performing a reading operation or a writing operation among the first conductive lines of the semiconductor memory device and outputs a selection signal to the semiconductor memory device. The second control unit selects the second conductive line corresponding to the memory cell performing a reading operation or a writing operation among the second conductive lines of the semiconductor memory device and outputs a selection signal to the semiconductor memory device. Further, the sensing unit senses the information stored in the memory cell selected by the first and second control units.

Here, the semiconductor memory device has a shape in which the memory layer contacts with the sidewall of the first conductive line and a portion of the second conductive line is embedded between the first conductive lines to easily control the contact area between the first and second conductive lines and the memory layer even at the high degree of the integration, thereby improving the operation characteristics thereof.

As a group of main products to which the memory chip in accordance with the embodiment of the present invention may be applied, there may be a computing memory used for a desk top computer, a notebook, and a server, a graphics memory of various specifications, and a mobile memory that has been spotlighted with the development of the mobile communication. In addition, the memory chip may be applied to portable storage media, such as a memory stick, MMC, SD, CF, an xD picture card, an USB flash device, or the like, and various digital applications such as MP3P, PMP, a digital camera and a camcorder, a mobile phone, or the like. Further, the memory chip may be applied to technologies such as a single article of the memory chip, a multi-chip package (MCP), a disc on chip (DOC), an embedded device, or the like. Further, the memory chip is applied to a CMOS image sensor (CIS) and may be supplied in various fields such as a camera phone, a web camera, small photographing equipment for medical, or the like.

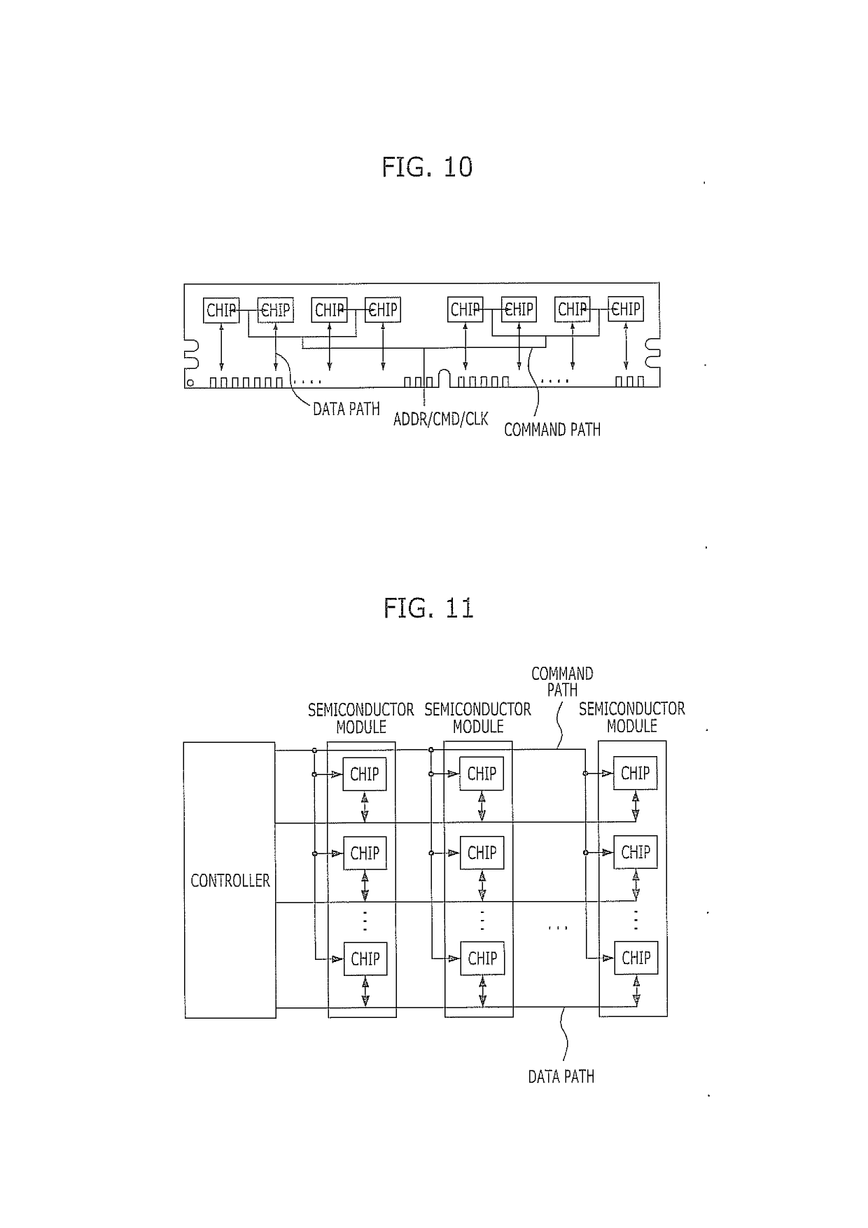

FIG. 10 is a block diagram illustrating a memory module in accordance with an embodiment of the present invention.

As illustrated in FIG. 10, the memory module includes a plurality of memory chips mounted on the module substrate, a command path enabling a memory chip to receive a control signal (address signal (ADDR), command signal (CMD), clock signal (CLK)) from an external controller (not illustrated), and a data path connected with a memory chip to transmit data.

Further, the command path and the data path may be formed like or similar to ones used in a general memory module.

In FIG. 10, 8 memory chips may be mounted on the front surface of the module substrate. Memory chips may similarly be mounted on the rear surface of the module substrate. That is, the memory chip may be mounted at one side or both sides of the module substrate and the number of mounted memory chips is not limited thereto. In addition, a material and a structure of the module substrate is not particularly limited.

Here, the semiconductor memory device in accordance with the embodiment of the present invention may be formed in the memory chip of the memory module to have a shape in which the memory layer contacts with the sidewall of the first conductive line and a portion of the second conductive line is embedded between the first conductive lines to easily control the contact area between the first and second conductive lines and the memory layer even at the high degree of the integration, thereby improving the operation characteristics thereof.

FIG. 11 is a block diagram illustrating a memory system in accordance with an embodiment of the present invention.

As illustrated in FIG. 11, the memory system includes a plurality of memory modules including at least one memory chip. Further, a memory controller communicating data and/or command/address signal to a memory module through a system bus is provided.

Here, the semiconductor memory device in accordance with the embodiments of the present invention may be formed in the memory chip of the memory system to have a shape in which the memory layer contacts with the sidewall of the first conductive line and a portion of the second conductive line is embedded between the first conductive lines to easily control the contact area between the first and second conductive lines and the memory layer even at the high degree of the integration, thereby improving the operation characteristics thereof.

In accordance with the embodiments of the present invention, the memory layer contacts with the sidewall of the first conductive line and a portion of the second conductive line is embedded between the first conductive lines, thereby easily controlling the contact area between the first and second conductive lines and the memory layer even at the high degree of the integration.

Further, in accordance with the embodiment of the present invention, the memory layer contacts with the sidewall of the first conductive line by removing the etching process at the time of the process of forming the memory layer. Thereby, the process of fabricating a semiconductor memory device may be simplified and the deterioration in characteristics due to the damage occurring at the time of etching the memory layer and deterioration in characteristics due to the by-products generated at the time of the etching process may be prevented.

Moreover, in accordance with the embodiment of the present invention, a portion of the second conductive line is embedded between the first conductive lines and therefore, the volume of the second conductive line is easily increased even at the high degree of the integration, thereby improving the signal transfer characteristics.

While the present invention has been described with respect to the specific embodiments, it will be apparent to those skilled in the art that various changes and modifications may be made without departing from the spirit and scope of the invention as defined in the following claims.

What is claimed is:

1. A semiconductor memory device comprising:
a plurality of first conductive lines;
a memory layer contacting with a first sidewall of each of the first conductive lines; and
a plurality of second conductive lines crossing the first conductive lines and contacting with the memory layer.

2. The semiconductor memory device of claim 1, wherein the memory layer contacts with a second sidewall of each of the first conductive lines.

3. The semiconductor memory device of claim 1, wherein the memory layer contacts the first sidewall of each of even-numbered ones of the first conductive lines while contacting a second sidewall of each of odd-numbered ones of the first conductive lines within a same respective trench.

4. The semiconductor memory device of claim 1, wherein each of the second conductive lines has a portion formed between the first conductive lines.

5. The semiconductor memory device of claim 1, wherein the memory layer includes variable resistance materials.

6. A semiconductor memory device comprising:
a plurality of first conductive lines formed over a substrate;
an insulating layer formed over the first conductive lines;
trenches exposing a first sidewall of each of the first conductive lines;
a memory layer formed over the exposed sidewall of each of the first conductive lines; and
a plurality of second conductive lines crossing the first conductive lines and filling the trenches.

7. The semiconductor memory device of claim 6, wherein each of the trenches has any one selected from a shape in which both sidewalls of each of the first conductive lines are exposed, a shape in which the first sidewall of each of the first conductive lines is exposed, and a shaped in which the first sidewall or a second sidewall of each of the first conductive lines is exposed.

8. The semiconductor memory device of claim 7, wherein when each of the trench has a shape in which the first sidewall or the second sidewall of each of the first conductive lines is exposed, each of the trenches exposes the first sidewall of each of even-numbered ones of the first conductive lines while exposing the second sidewall of each of odd-numbered ones of the first conductive lines.

9. The semiconductor memory device of claim 6, wherein bottom surfaces of the trenches are formed below the top surface of the substrate.

10. The semiconductor memory device of claim 6, wherein top sides of the trenches are round.

11. The semiconductor memory device of claim 6, wherein the memory layer is formed over the surfaces of the trenches or formed over the surfaces of the trenches and the insulating layer.

12. The semiconductor memory device of claim 6, wherein the memory layer includes variable resistance materials.

13. The semiconductor memory device of claim 6, wherein each of the second conductive lines includes:
a first conductive layer filling the trenches; and
a second conductive layer formed over the first conductive layer and crossing the first conductive lines.

14. The semiconductor memory device of claim 6, wherein the insulating layer is formed over a second sidewall and a top surface of each of the first conductive lines.

15. A method for fabricating a semiconductor memory device, comprising:
forming a plurality of first conductive lines over a substrate;
forming an insulating layer over the substrate including the first conductive lines;
forming trenches exposing sidewalls of the first conductive lines by selectively etching the insulating layer;
forming a memory layer over the exposed sidewalls of the first conductive lines; and
forming a plurality of second conductive lines crossing the first conductive lines and filling the trenches.

16. The method of claim 15, wherein the forming of the trenches includes etching the first conductive lines along centerlines thereof until the substrate below the centerlines is exposed.

17. The method of claim 15, wherein the insulating layer is formed along a surface of the substrate including the first conductive line.

18. The method of claim 15, wherein the forming of the trenches includes etching the insulating layer between the first conductive lines to expose a first sidewall of each of the first conductive lines.

19. The method of claim 15, wherein the forming of the trenches includes etching the insulating layer between the first conductive lines to expose a first sidewall or a second sidewall of each of the first conductive lines.

20. The method of claim 15, wherein the forming of the trenches includes etching the insulating layer alternately between the first conductive lines to expose a first sidewall of each of the first conductive lines.

21. The method of claim 15, wherein at the forming of the trenches, the substrate is partially etched to bottom parts of the trenches.

22. The method of claim 15, further comprising rounding top sides of the trenches after the forming of the trenches.

23. The method of claim 15, wherein at the forming of the memory layer, the memory layer is formed along a surface of a structure including the trenches.

24. The method of claim 15, wherein the memory layer includes variable resistance materials.

25. The method of claim 15, wherein the forming of the second conductive lines includes:
forming a first conductive layer filling the trenches;
forming a second conductive layer over the substrate; and
etching the first and second conductive layers.
